(19) United States
(12) Patent Application Publication
(10) Pub. No.: US 2015/0145144 A1
(43) Pub. Date: May 28, 2015

(54) USE OF A CONFORMAL COATING ELASTIC CUSHION TO REDUCE THROUGH SILICON VIAS (TSV) STRESS IN 3-DIMENSIONAL INTEGRATION

(71) Applicant: Rensselaer Polytechnic Institute, Troy, NY (US)

(72) Inventor: John F. McDonald, Clifton Park, NY (US)

(21) Appl. No.: 14/402,423

(22) PCT Filed: Jun. 6, 2013
(86) PCT No.: PCT/US2013/044451

§ 371 Date: Nov. 20, 2014

Related U.S. Application Data
(60) Provisional application No. 61/689,531, filed on Jun. 7, 2012.

(51) Int. Cl. H01L 23/48; H01L 21/768; H01L 25/065

(52) U.S. Cl. CPC H01L 23/481; H01L 25/0657; H01L 21/76898; H01L 2225/06541
USPC 257/774; 438/108

(57) ABSTRACT

Integrated circuit assemblies, as well as methods for creating the same, are provided. The integrated circuit assembly includes a first chip and a second chip, including respective face surfaces, wherein the first chip and the second chip are bonded in a face-against-face contact configuration. The integrated circuit assembly includes a via disposed to pass through the first chip and the second chip. The via is surrounded by at least one material of the respective first chip and the second chip. A cushion layer encapsulating at least a portion of the via is formed between the via and the at least one material surrounding the via.

### CROSS REFERENCE TO RELATED APPLICATIONS

The present application is related to U.S. Provisional Application Ser. No. 61/689,531, entitled USE OF A CONFORMAL COATING ELASTIC CUSHION TO REDUCE TSV STRESS IN 3D INTEGRATION. The U.S. Provisional Application was filed on Jun. 7, 2012, the contents of which are incorporated fully herein by reference.

### FIELD OF THE INVENTION

The present invention generally relates to three-dimensional (3D) integrated assemblies, and, more particularly, to three-dimensional (3D) integrated circuit assemblies having a cushion layer.

### BACKGROUND OF THE INVENTION

Today's integrated circuits often include many (up to millions, or greater) integrated components and devices. However, for a given product, it sometimes is not possible to achieve on one integrated substrate (or integrated circuits, also known as chips) all of the circuitry or performance required. Thus, two or more substrates may be required. Also, fabrication process limitations sometimes dictate the use of two or more substrates for manufacturing different components. A major challenge then becomes the interconnection of the circuitry on multiple substrates. There may be hundreds of connections required between chips and it is necessary to keep connection resistance low and path lengths short to minimize inductive and capacitive effects, permitting high speed operation. While numerous interconnection arrangements and processes are known, many require special, complicated processes or expensive structures.

Additionally, as the number of components and devices on integrated circuits continues to increase, there exists an increasing number and complexity of on-chip wires used to connect the various components and devices, and to connect internal components and devices to external circuitry. These interconnections may be space-consuming, forcing the length of the interconnections to be longer and thus introducing more delay in signal propagation along these on-chip wires. Introducing additional wiring layers can result in a reduction of wiring lengths, but the formation or fabrication of such additional wiring layers may require additional or complicated processing steps. In addition, the cost of making interconnections is often a critical factor in determining the number of interconnections that may be used if a product is to sell.

A way to reduce the length of interconnections (and the corresponding wiring delay, coupling capacitance between wires, loss mechanisms, and other unwanted wire parasitics) is to position the devices to be interconnected in a three-dimensional (3D) spatial arrangement. Part of the wire congestion in two-dimensional (2D) spatial arrangements comes from the inability to optimally place the components to be connected. A 3D arrangement allows more possibilities for attaining optimal placement of components and devices. To attain the maximum advantage of wire shortening, however, the wires must be directed vertically through vias between the 3D stacked circuits anywhere within the volume of the circuitry, and not just around the periphery of the stack. FIG. 1 illustrates an example of a 3D chip stack with vertical vias in the interior of the stack. The chip stack 100 includes substrates 110, 120, 130, and 140. Examples of vertical vias are shown as 112, 114, and 116.

Another 3D configuration utilizes two substrates stacked in a face-against-face configuration, as illustrated in FIGS. 2A and 2B. The term face-against-face implies that the surfaces of the substrates that contain the devices and their contacts, called the faces, will be bonded facing each other. As shown, the two substrates 210 and 220 are aligned and bonded with their respective face surfaces facing each other. In such a configuration, a via may be used to form an interconnection. The via may pass through one of more of the substrates 210, 220, to form the interconnection. If the substrates are made of silicon (Si), the via passing through the substrate may be known as a through silicon via (TSV). Conventionally, the TSV is comprised of material that is different than the material forming the substrate. As a result, problems may arise when the material forming the via, and the material forming the substrate, are heated.

Thus, a structure and method of forming improved compact integrated circuit assemblies and interconnections is needed. Preferably, this structure and method will enable 3D circuits to be exposed to increased temperatures.

### SUMMARY OF THE INVENTION

According to aspects of the invention, an integrated circuit assembly is provided. The integrated circuit assembly includes a first chip and a second chip. The first chip has a face surface that includes at least one first device, and a back surface. The second chip has a face surface comprising at least one second device. The first chip and the second chip are bonded in a face-against-face contact configuration. The integrated circuit assembly further includes a via. The via has a pillar portion, wherein the pillar portion is disposed to pass through the first chip and the second chip. The via is surrounded by at least one material of the respective first chip and the second chip. A cushion layer encapsulating at least a portion of the via is formed between the via and the at least one material surrounding the via.

According to other aspects of the invention, a method for interconnecting a first chip and a second chip is provided. The method includes a bonding step, a forming step, and a depositing step. The first step of the method for interconnecting a first chip and a second chip includes bonding the first chip and the second chip in a face-against-face configuration. The second step includes forming a via at least partially within the first chip and the second chip, wherein the via is surrounded by at least one material of the respective first chip and the second chip. The third step includes depositing a cushion layer on a portion of the via, wherein the cushion layer is formed between the via and the at least one material surrounding the via.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a diagrammatic illustration of a conventional 3D chip stack with vertical vias in the interior of the stack;

FIGS. 2A and 2B are diagrammatic illustrations of the alignment action for face-against-face wafer substrate alignment for monolithic fabrication of conventional 3D die assemblies, and the face-against-face bonding of two aligned substrates for monolithic 3D circuit lamination, respectively;

FIGS. 3A-3C are diagrammatic cross-sectional illustrations of an example of the alignment and face-against-face bonding of chips, as well as the backside thinning of one of the substrates of one of the chips;

FIGS. 4A-4U are diagrammatic cross-sectional illustrations of a process of fabricating a two-chip structure with a deep pillar nail head via in accordance with an aspect of the present invention; and

FIGS. 5A-5C are diagrammatic cross-sectional illustrations of an example of a through silicon via (TSV) located within a die.

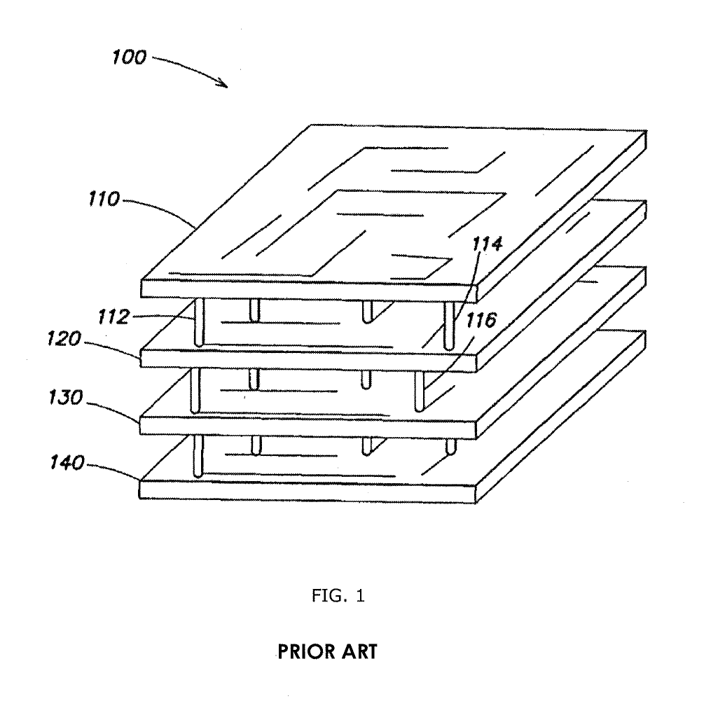

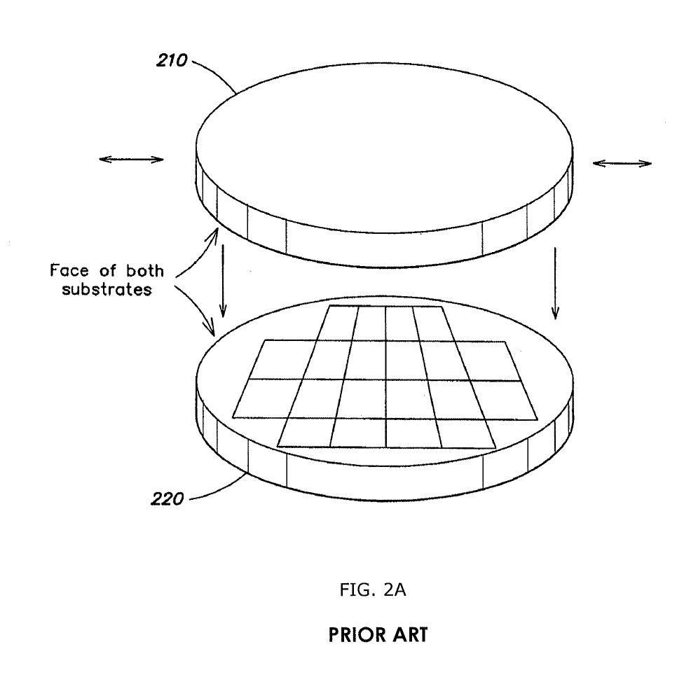

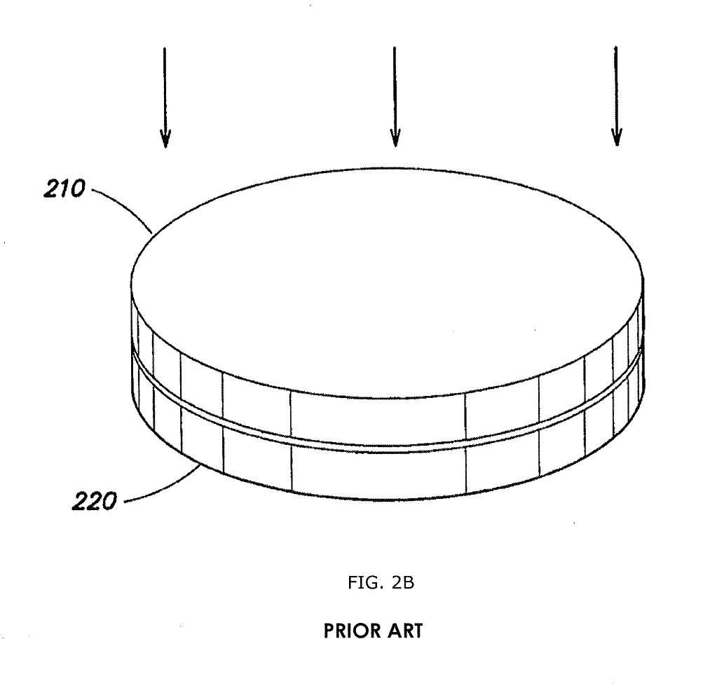

### DETAILED DESCRIPTION OF THE INVENTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing”, “involving”, and variations thereof herein, is meant to encompass the items listed thereafter and equivalents thereof as well as additional items. In this application, the phrase “at least one of A and B” is equivalent to A and/or B, meaning A or B or (A and B).

It should also be noted that in describing the semiconductor structures that follow, the term “on” will be used to describe the placement of devices, layers and features relative to each other. The term “on” in such situations is not meant to be limited to an interpretation of “directly on,” and is not meant to exclude the possibility of structures being disposed within layers, or at least partially within layers, or the possibility of the presence of intervening layers. Thus, “on” can include “in,” “partially in,” and “over” as appropriate to the situation.

It is further noted that for purposes of this application, the term “substrate” refers to a support upon which, in which or partially within which layers, structures and/or devices may be formed. The term “chip” as used herein refers to a substrate plus any layers, structures or devices formed on, within or partially within the substrate. A “chip” is often commonly referred to as a “die” or as an “integrated circuit,” but an integrated circuit may include additional components such as a lead frame, bond wires and packaging; and an integrated circuit may include multiple chips in one package.

A compact three-dimensional structure of an integrated circuit assembly is provided. A corresponding method for fabricating the structure is also provided. The structure includes a first substrate (sometimes called a wafer) having a front surface, upon or in which components and devices may be formed, thus forming a first chip. The face of the chip corresponds to the active side of the chip, or the side with the components and/or devices. The structure further includes a second substrate having a front surface, upon or in which components and devices may be formed, thus forming a second chip. The face of the second chip corresponds to the active side of the chip, or the side with the components and/or devices. The first chip and second chip are bonded together, with the respective faces of the chips facing each other.

A deep via, which is termed a “pillar” via, formed at least partially within a single trench in one of the chips, is provided to connect metallization layers of the two chips. According to some embodiments, the chips are bonded together with a suitable bonding agent, for example, an appropriate adhesive. The pillar via may be formed through a substrate of one of the chips, thus exposing the pillar at a backside of the substrate. According to some embodiments, a first pair of face-against-face bonded chips may be bonded in an appropriate configuration to a second pair of face-against-face bonded chips, thus forming a multi-chip integrated circuit assembly. For example, in some embodiments, a back surface of a substrate of a first face-against-face bonded chip stack, having exposed pillars, will be treated as a new face for subsequent face-against-face bonding with a back surface of a substrate of a second face-against-face bonded chip stack.

An interconnection for a three-dimensional integrated circuit assembly is provided, along with a method of forming the interconnection. The interconnection may take the form of a via which enables connecting a metal layer of a first chip to a metal layer of a second chip, wherein the first and second chips are bonded in a face-against-face configuration. In some embodiments, the via is disposed at least partially within the opening of a collet, which provides contact to a metal layer of the first chip. The collet may be a ring-like structure that may take the form of a closed (but not necessarily round) contour. Alternatively, the collet may include one or more breaks, forming a segmented contour through which the via passes. According to one embodiment, the via includes two portions. The first portion is a pillar, which is formed at least partially within a single tunnel and extends from a layer of the first chip to a layer of the second chip. The second portion of the via includes a “nail head” structure which contacts the collet, and has a greater cross-sectional area than does the pillar portion of the via.

A low-resistance via for connecting metallization layers of chips bonded in a face-against-face configuration is provided. The via includes a single tunnel structure, and thus occupies a relatively small amount of chip area or volume in the 3D assembly. According to some embodiments, the via is fabricated after the chips have been bonded together. A substrate of one or both of the chips may be thinned after the chips have been bonded together in order to facilitate the via fabrication. According to some embodiments, no portion of the via is formed prior to the bonding of the chips. That is, the via is formed after the chips are aligned and bonded. This “vias in last” approach enables the use of many cleaning processes during the fabrication of the via structure to ensure good contacts and clean surfaces of the via, tunnels, and other fabrication structures. The structure is also inexpensive to make, uses the same processes as are used for semiconductor fabrication, allows for the formation of a high density via array, and exhibits a low inductance due to its relatively short length. These same electrical vias can also serve as thermal pathways to enhance the removal of heat from the interior of the 3D assembly because most metals are also thermally conductive. Of these metals the highest electrical and thermal conductivity at room temperature typically would be obtained with copper (Cu). The via may also have substantially vertical sidewalls, obtained from high-aspect-ratio processing. The use of copper may help aid the formation of the vertical sidewalls.

It should be appreciated that the aspects and embodiments of the invention listed are not necessarily distinct, but that they may be practiced in any suitable combination. Likewise, the invention is not limited to the aspects and embodiments explicitly described herein, but is capable of additional and alternative aspects and embodiments, as will be apparent to those of skill in the art.

### Alignment, Bonding, and Backside Thinning

A deep pillar nail head via is known. For an example of a deep pillar nail head via, see THREE-DIMENSIONAL FACE-AGAINST-FACE INTEGRATION ASSEMBLY, U.S. Pat. No. 7,453,150. For illustration purposes, a cushion layer of the present invention will be described in relation to deep pillar nail head vias. Aspects of the present invention, however, are not limited to deep pillar nail head vias. Those skilled in the art will understand that aspects of the present invention may be used with deep pillar nail head pillars, as described in U.S. Pat. No. 7,453,150, as well as other vias.

In order to fabricate a deep pillar nail head via, it is desired to attain a face-against-face bonded configuration of two chips, with the backside of a substrate of at least one of the chips being thinned. The face-against-face configuration provides advantages over other known configurations, e.g., back-against-face configurations. One advantage that a face-against-face configuration provides over a back-against-face configuration, for example, includes permitting the top substrate to be thinned after aligning the top substrate with the bottom substrate. Because the top substrate is thick (i.e., not thinned) during alignment when using a face-against-face configuration, the top substrate is less likely to bend, stretch, warp, or blister than substrates used in face-against-back configurations. As a result, circuits using the face-against-face configuration are more accurately aligned than chips using other configurations, e.g. the face-against-back configuration. The invention, however, is not limited to any specific method of attaining this configuration. A non-limiting example is now described.

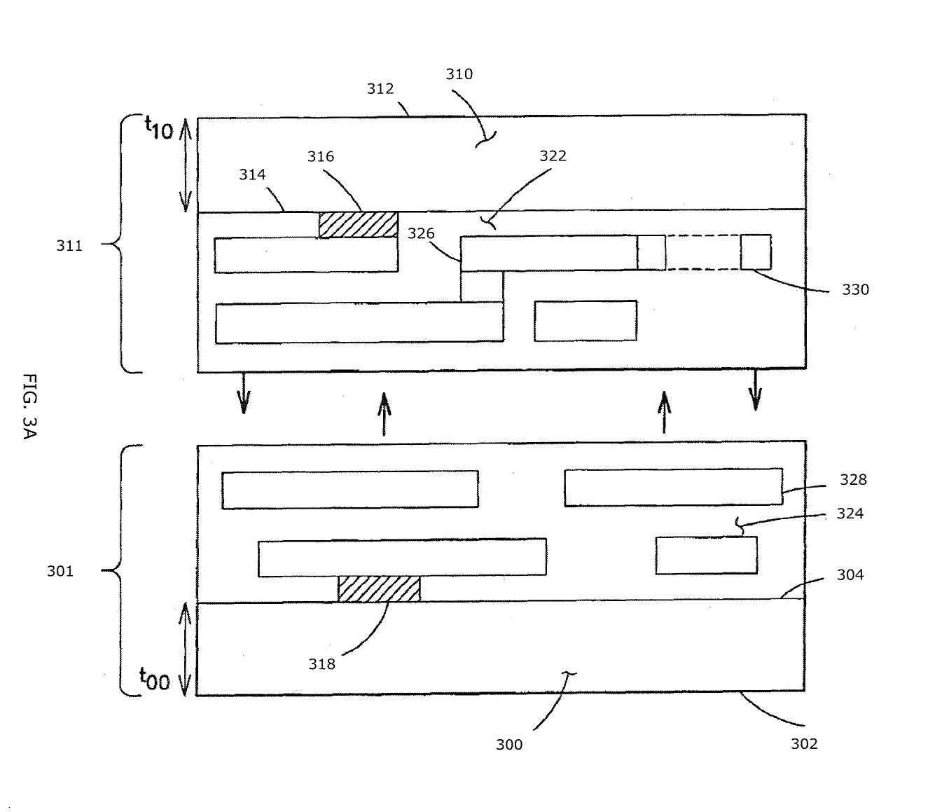

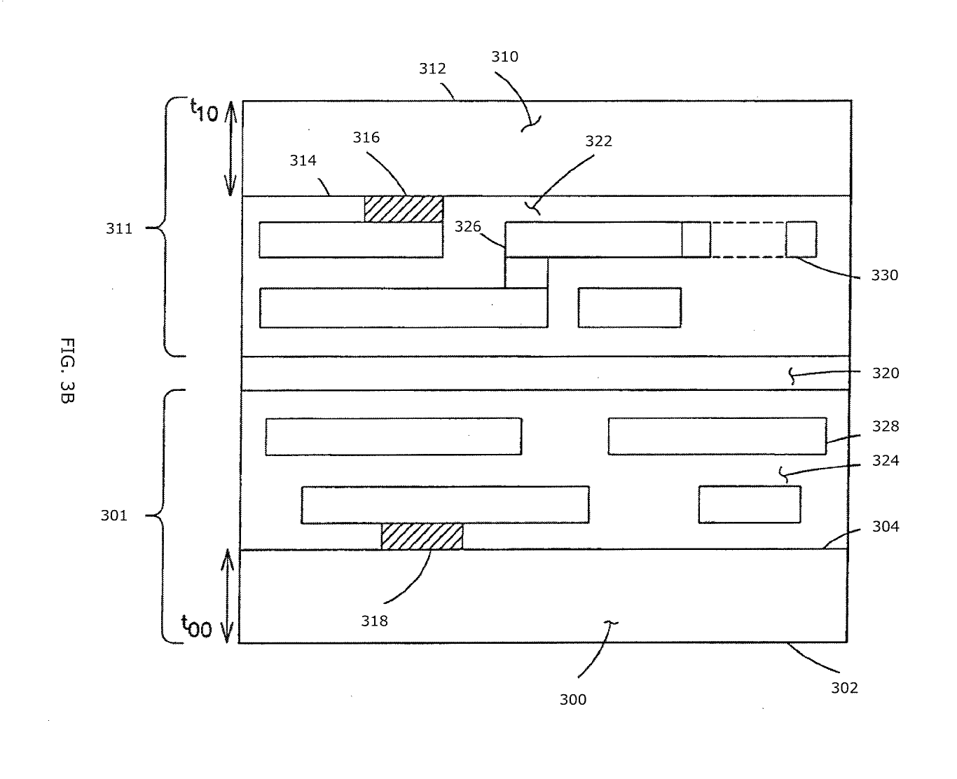

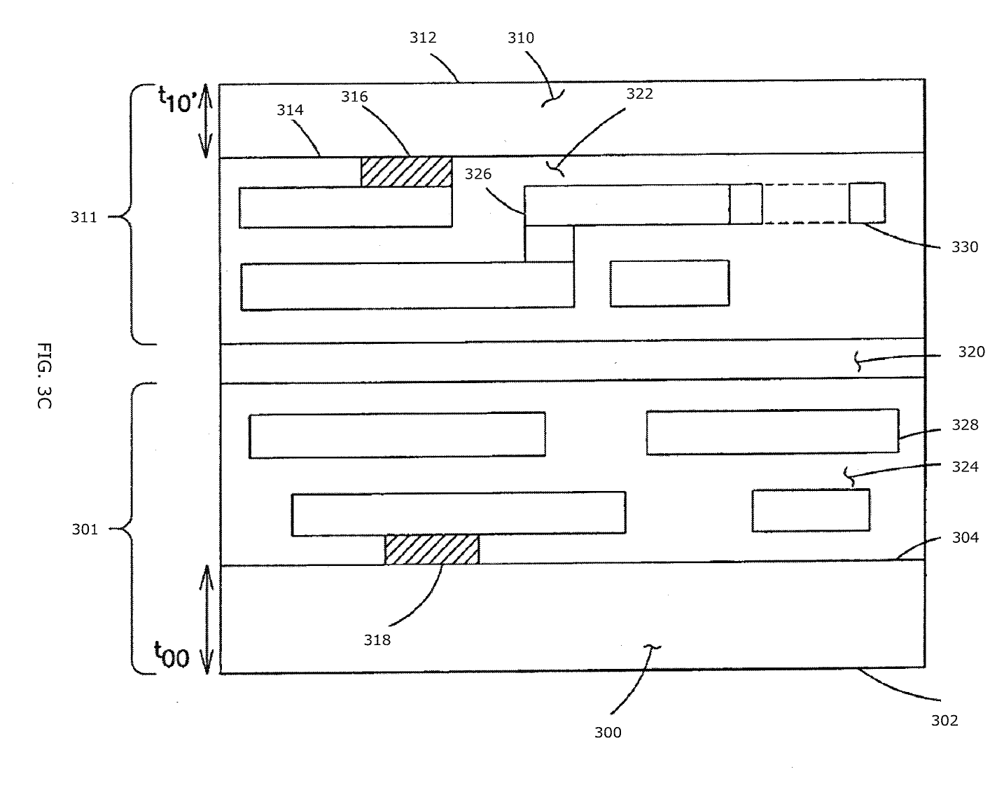

Prior to bonding, processing may be performed on one or both of two substrates to provide desired components, metallization layers, etc., thereby forming two chips. Referring to FIG. 3A, a chip 301 comprises a substrate 300 having a front surface 304 and a back surface 302. The substrate 300 is a silicon substrate, but could be any other type of substrate, as the invention is not limited in this respect. Substrate 300 has a thickness t₀₀, which may be as small as 600-800 microns, or any other thickness, as the invention is not limited in this respect. A dielectric layer 324, which may have a low dielectric constant, K, may be formed on the front surface 304. The dielectric layer 324 may be silicon dioxide, or any other suitable inter-metallic dielectric (IMD) material, as the invention is not limited in this respect. One or more metallization layers 328 may be formed within the dielectric layer 324, and may be formed of copper, aluminum, or any other suitable conducting material, as would be known to those of skill in the art.

Contact layer 318, which may be used to provide an ohmic contact between a metallization layer 328 and substrate 300, may be formed on the front surface 304 of substrate 300. The contact layer 318 may be formed of tungsten, or any other suitable contact material. Contact metal can be used to avoid the formation of a Schottky diode instead of an ohmic contact with the device terminals implemented in the substrate or on its face. Appropriate interface metallurgy, as would be known to those of skill in the art, may be used to form the contact layer 318, and to ensure proper contact of contact layer 318 with substrate 300 and metallization layer 328.

A chip 311 comprises a substrate 310 having a front surface 314 and a back surface 312. The substrate 310 is a silicon substrate, but could be any other type of substrate, as the invention is not limited in this respect. Substrate 310 has a thickness t₁₀, which may be as little as 600-800 microns, or any other thickness, as the invention is not limited in this respect. A dielectric layer 322, which may have a low dielectric constant, K, may be formed on the front surface 314. The dielectric layer 322 may be SiO₂, or any other suitable inter-metallic dielectric material, as the invention is not limited in this respect. One or more metallization layers 326 may be formed within dielectric layer 322, and may be formed of copper, aluminum, or any other suitable conducting material, as would be known to those of skill in the art. Contact layer 316, which may be used to provide an ohmic contact between a metallization layer 326 and substrate 310, may be formed on the front surface 314 of substrate 310. The contact layer 316 may be formed of tungsten, or any other suitable contact material. Appropriate interface metallurgy, as would be known to those of skill in the art, may be used to form the contact layer 316, and to ensure proper contact of contact layer 316 with substrate 310 and metallization layer 326.

Collet 330 is formed at least partially within dielectric layer 322. The collet may contact a metallization layer 326. The collet 330 may be formed of copper, aluminum, or any other suitable material for forming a good contact with the deep pillar nail head via and metallization layer 326.

In anticipation of bonding the two chips 301 and 311 in a face-against-face configuration, a variety of processing steps may be required. The face surface of each chip should be polished to be as flat as possible. Using a deep trench etching process, a trench in the form of a back side alignment mark can be etched part way into the front surface of what will become the thinned substrate partner in a two-chip stack. These trenches will be uncovered in the thinning process, at which point this mark will become visible and useful for backside lithography on the thinned substrate partner. Finally, the front side of the chip needs to be made adhesion-ready, such as by plasma activation of the surfaces or by application of a chemical adhesive by vapor or liquid application methods. This adhesive should be chemically specific for adhering to the face of the chip, contain latent chemistry for adhering to a second adhesion layer, but be capable of existing in a dry state for handling during chip-to-chip alignment and insertion into the bonder.

Prior to alignment, one or both faces is/are coated with a bonding layer, such as bonding layer 320 (shown in FIG. 3B). Bonding layer 320 may be a siloxane-based polymeric glue layer. However, alternative bonding layers may be used, for example, epoxy, polyimide, polymethyl siloxane, benzocyclobutene, siloxane copolymers, polyxylylenes, or any other bonding layer. Bonding preparation may also be promoted by plasma activation of the surfaces. It is desired to use a bonding layer that exhibits high thermal stability, a low coefficient of thermal expansion, good adhesion, low resistance to etching, and/or low degradation. Any of these properties or combination of properties may be sought in dependence on the intended application and environment of the structures, and the invention is not limited in this respect.

Due to the face-against-face configuration, in one implementation the alignment can be performed using two imagers. A first imager may be disposed below the chips and may view front surface 314 of substrate 310. A second imager may be disposed above the chips and may view the front surface 304 of substrate 300. Two alignment marks may be aligned on each substrate, the marks being separated from each other by a distance of approximately ¾ of the substrate diameter, although other distances and numbers of alignment marks may be used, or other alignment techniques, as the invention is not limited in this respect.

After the chips are aligned, they may be placed in a bonder in a chuck suitably designed to hold the two chips in horizontal (x-y) alignment while keeping them separated by a small amount in the z-direction for the bonding process to complete. The bonding may be performed by any suitable method. In one embodiment, the bonder heats the two substrates from their backsides and then carefully moves the two substrates together in the z-direction while maintaining their x-y alignment. Due to the indicated thicknesses of substrates 300 and 310, the substrates may be substantially rigid, facilitating their bonding without wrinkling, cracking, or otherwise sustaining damage. The completed face-against-face configuration is shown in FIG. 3B.

FIG. 3C illustrates the face-against-face configuration of FIG. 3B wherein the substrate 310 has been thinned from the back surface 312. The thinning may be performed by any suitable method for thinning silicon, for example, lapping, wet etching, or plasma thinning. Substrate 310, which had an initial thickness t₁₀, now has a thinned thickness t_{10′}, through which a hole or trench may be etched more easily than through the initial thickness t₁₀. The thinned substrate may also exhibit a greater optical transparency than an un-thinned substrate, thus facilitating further optical processing and/or aligning. The thinned thickness t_{10′} may be 200 angstroms to 10 microns, or any other suitable reduced thickness. If the thickness remaining after thinning is too large to acquire the registration information, special substrate preparation steps can be used to insert deep trench features from the front surface of the substrate, which will be exposed after thinning and then be used for registration.

The thinned substrate should have a highly uniform thickness. This may be achieved by any suitable method. For example, one method is to use an etching process that selectively stops etching or substantially slows the etching process at a buried oxide layer, such as is normally used in a silicon on insulator (SOI) wafer process. Specifically, substrate 310 may be formed using SOI technology, using materials with contrasting etch resistances. The contrasting etch resistances may facilitate uniform thinning of substrate 310.

If the wafer substrates are not SOI structures, other buried layers such as SiGe alloy layers, or heavily doped layers can be selective enough to slow or substantially end the thinning process. For instance, although not shown, substrate 310 may initially comprise a silicon substrate, a thin deposited SiGe layer, and epitaxial Si grown on the SiGe layer. The front surface 314 may correspond to a surface of the epitaxial layer, with the back surface 312 corresponding to a surface of the silicon substrate. After bonding chips 301 and 311 in the face-against-face configuration, the thinning process may function to thin the silicon substrate, stopping at the deposited SiGe layer, and thus leaving the SiGe layer and the epitaxial silicon layer intact.

Other techniques of thinning could involve adding additional deep trench structures from the face side of the wafer, filling them with an appropriate material that would be exposed during the thinning process and either slow down the etching process or serve as a signal indicator for regional thinning that the desired thickness has been locally achieved. For example, substrate 310 may comprise studs of any suitable material, such as tungsten formed from the front surface 314. Upon thinning substrate 310 from the back surface 312, after bonding, the tips of the studs may become exposed and either hinder any further thinning, or otherwise indicate that thinning is completed. Such a technique could be used with a regional plasma plume for example, sensing the exposure of the deep trench isolation (DTI) through the erosion of the material in the DTI structure by, say, a residual gas analyzer or other signaling means.

The method of thinning the substrate may be chosen depending on the type of stopping layer used, or vice-versa. By following the process of the above-described non-limiting example, a face-against-face bonded configuration with a uniformly thinned substrate may be obtained.

### Formation of Pillar Via with Nail Head

An exemplary fabrication sequence will now be described, according to aspects of the present invention. The fabrication sequence described below is only one embodiment of many other possible embodiments. It should be appreciated that such specific examples are not intended to be limiting. One of ordinary skill in the art will understand that various other fabrication sequences also may be used, according to aspects of the present invention.

The exemplary fabrication sequence will be described in relation to a formation of a pillar via with a nail head, assuming a face-against-face bonded, and thinned, configuration as the starting point (for example, the structure of FIG. 3C). For purposes of simplicity, specific values and/or characteristics of the process (such as aspect ratios, etchants, structure dimensions, etc.) will be listed, where appropriate. Furthermore, it should be appreciated that the discussed order of processing steps is intended as illustrative and non-limiting, and that the steps may be performed in various orders. Additional processing steps may be added, and not all of the steps discussed herein are required.

### Process Sequence

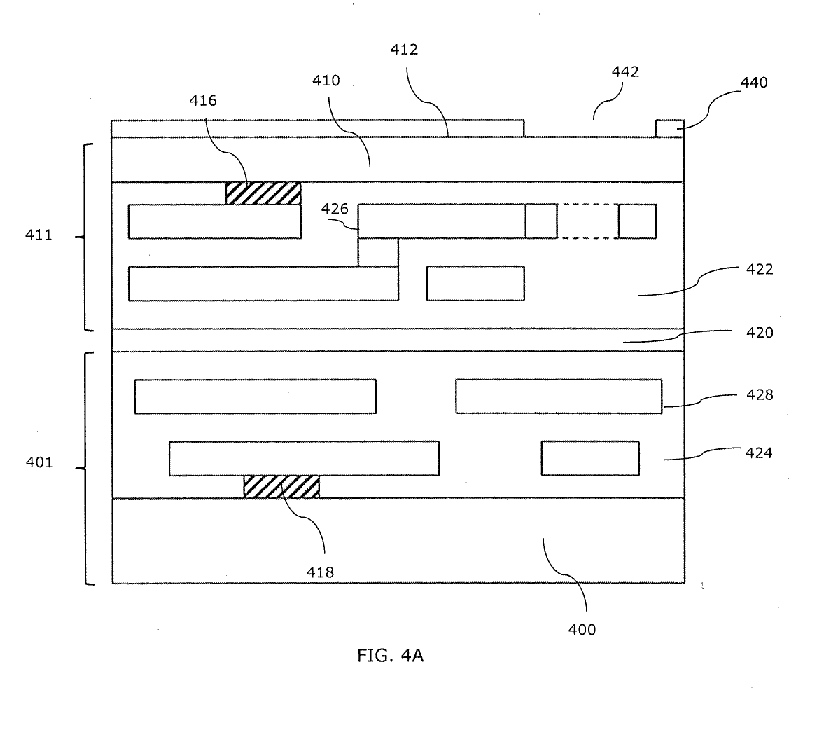

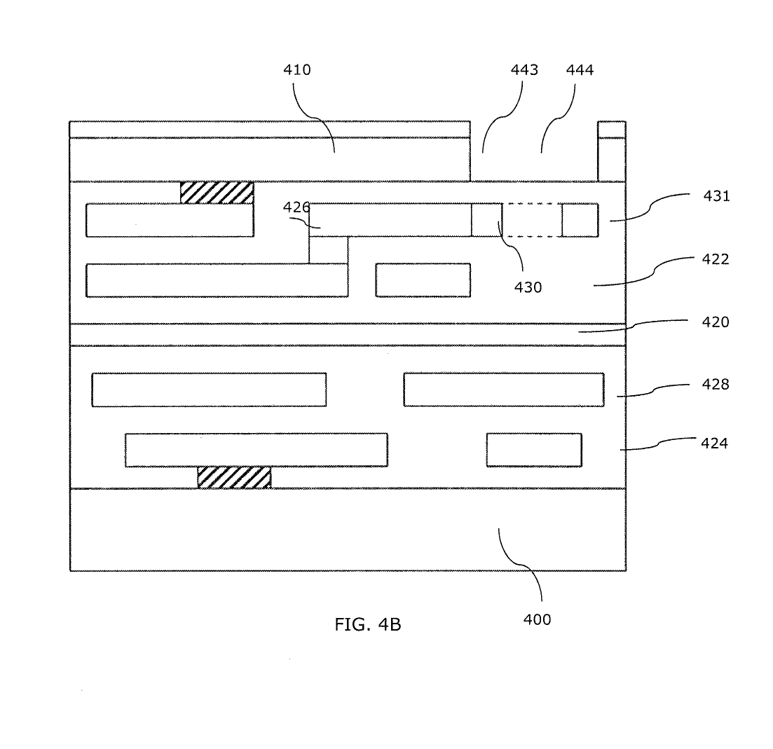

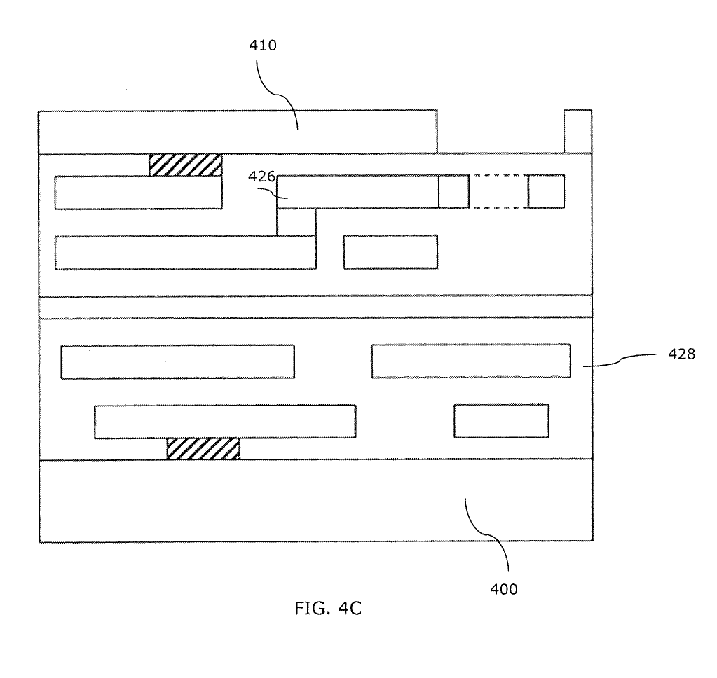

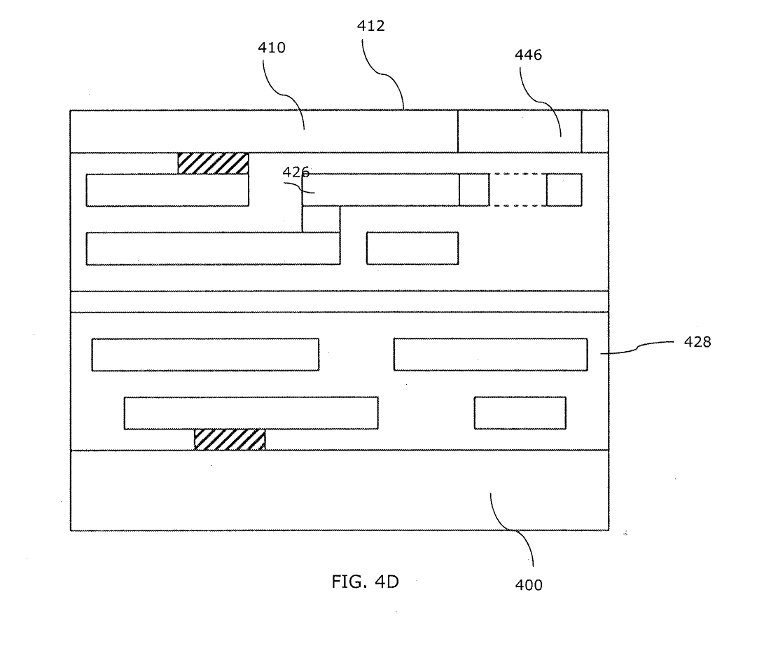

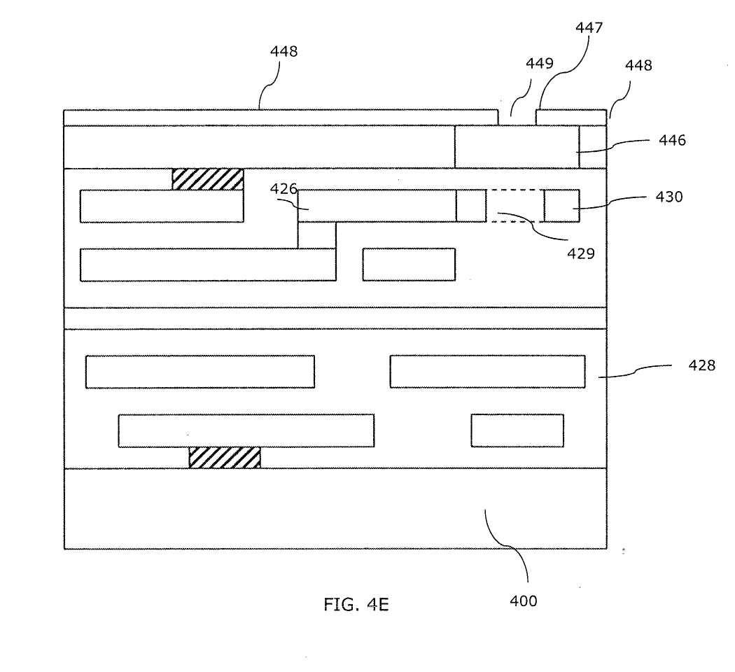

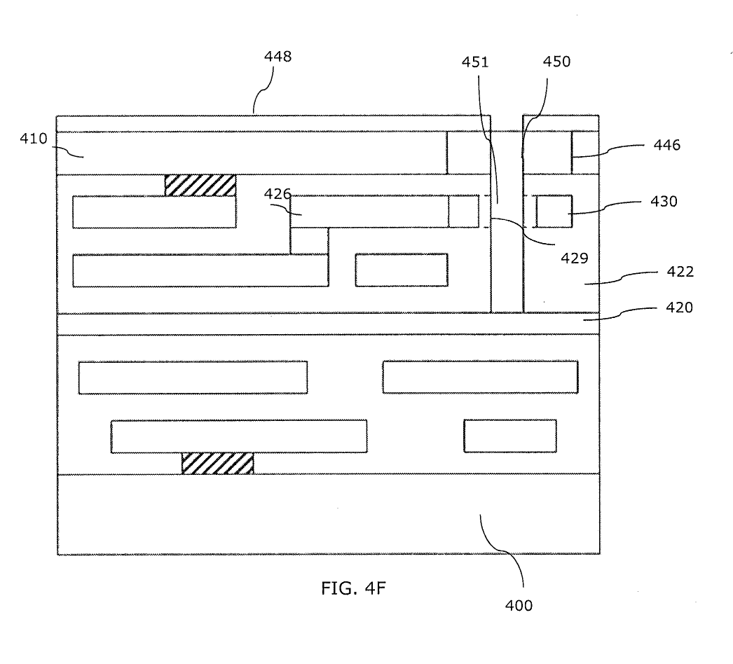

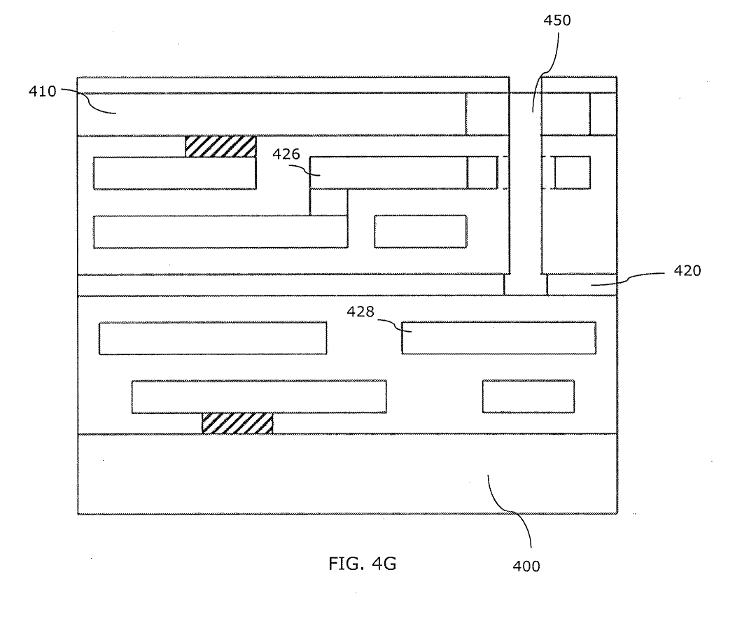

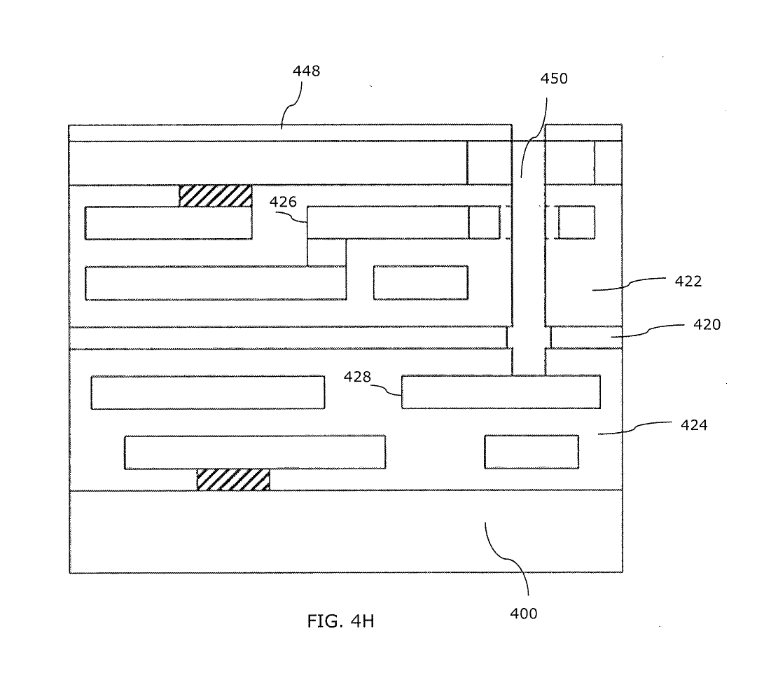

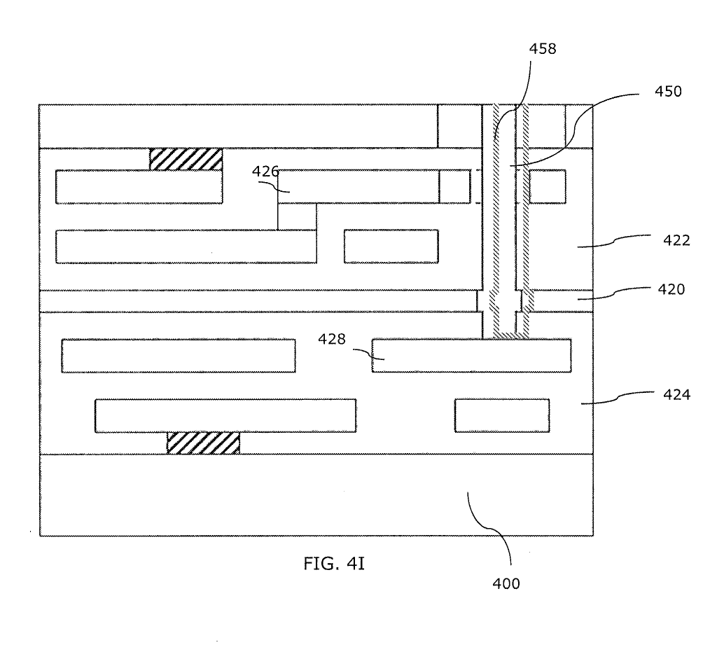

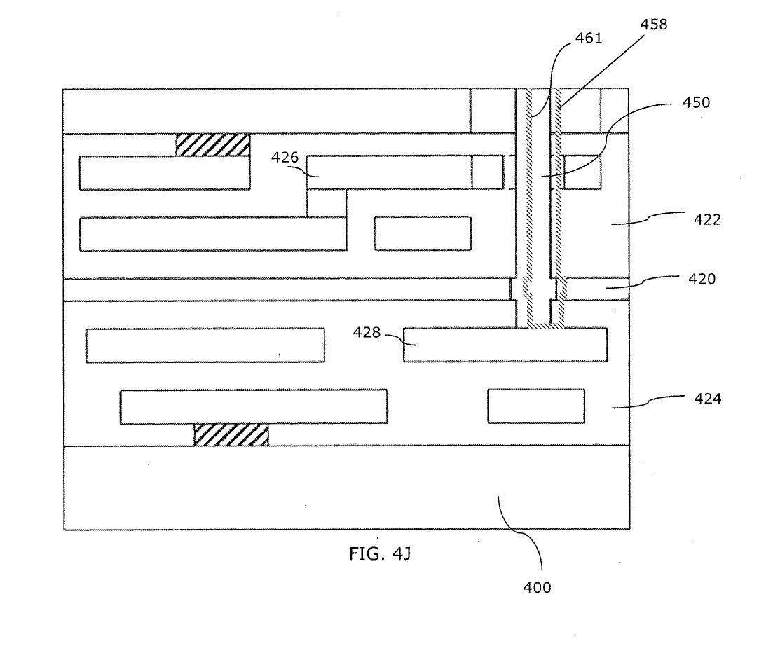

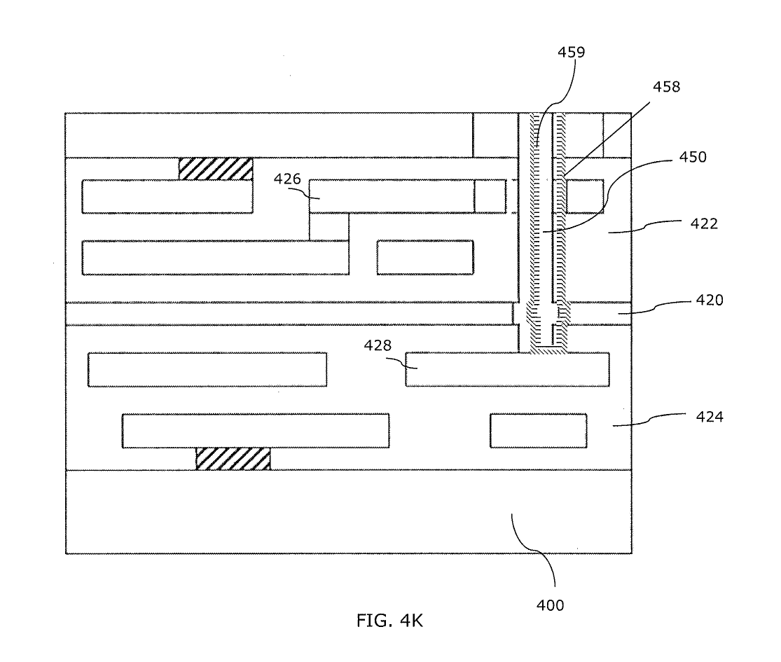

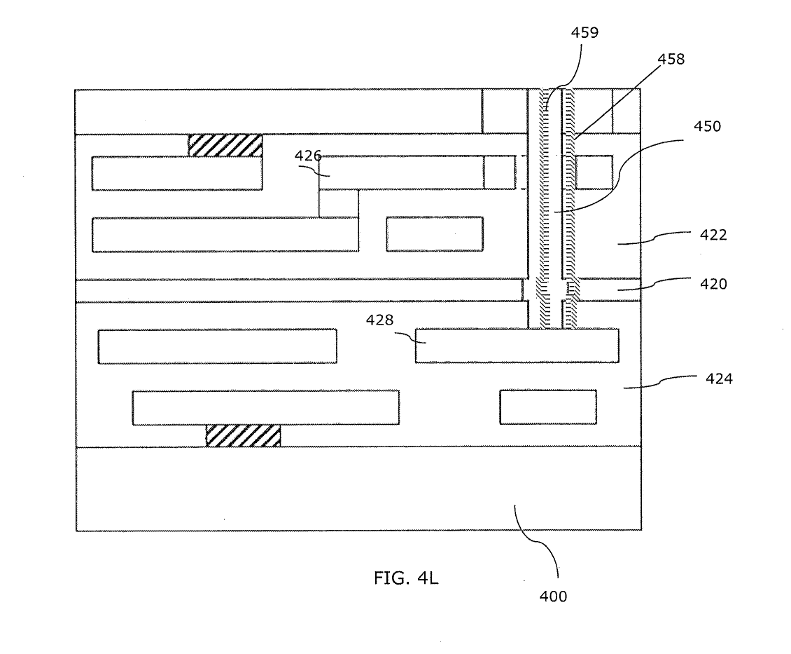

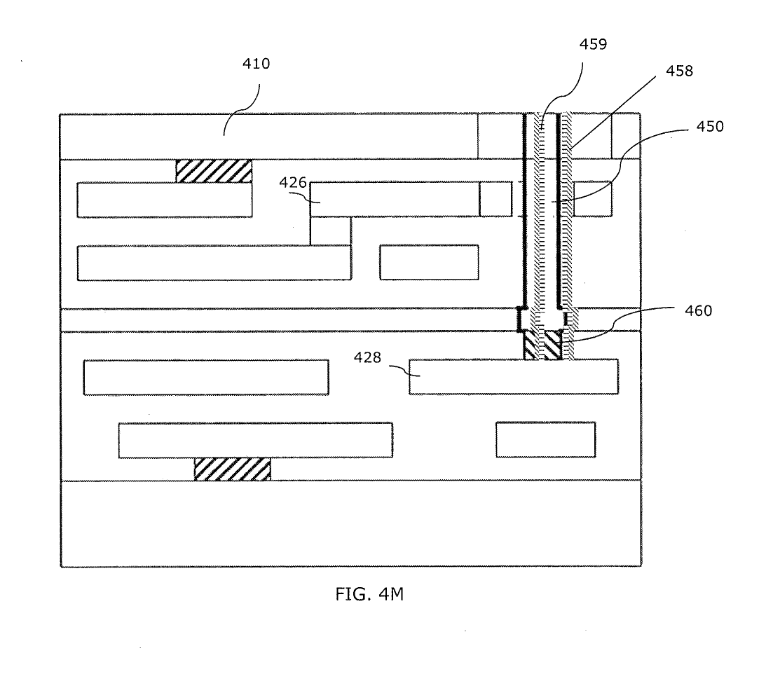

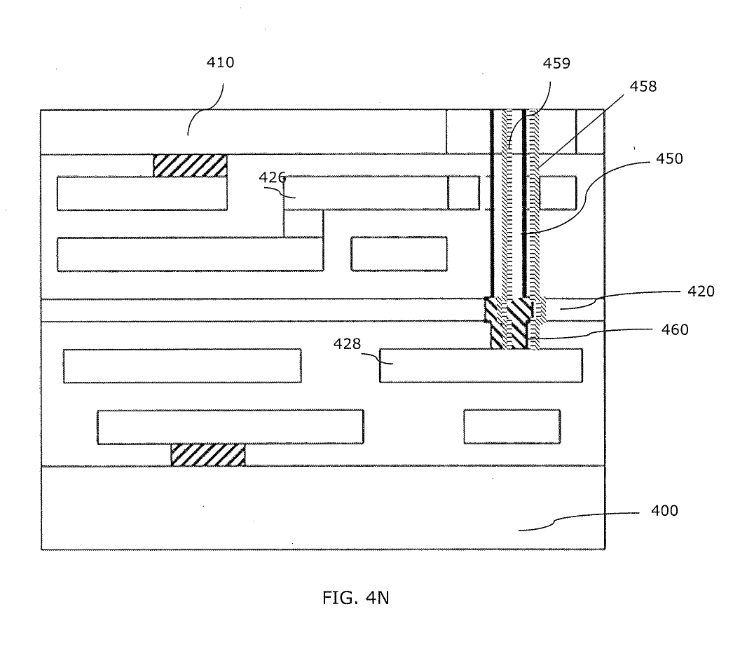

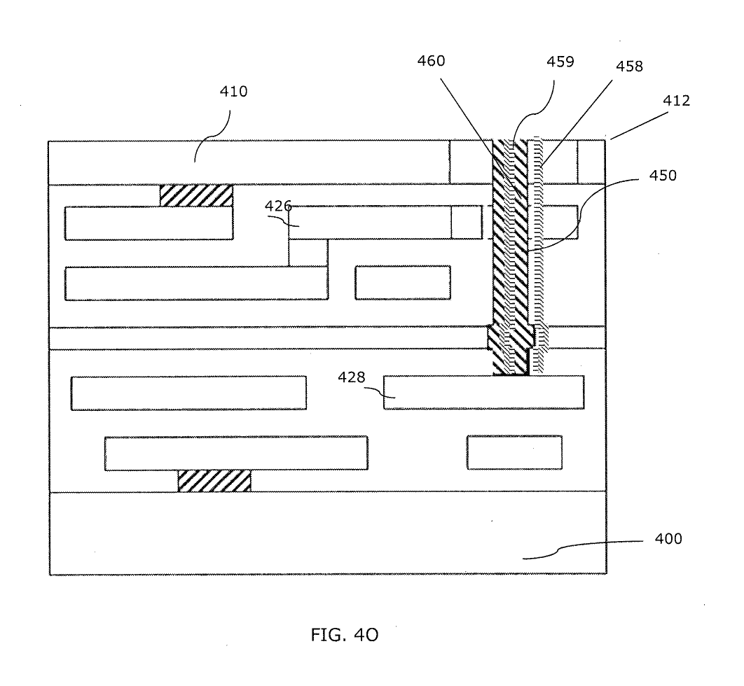

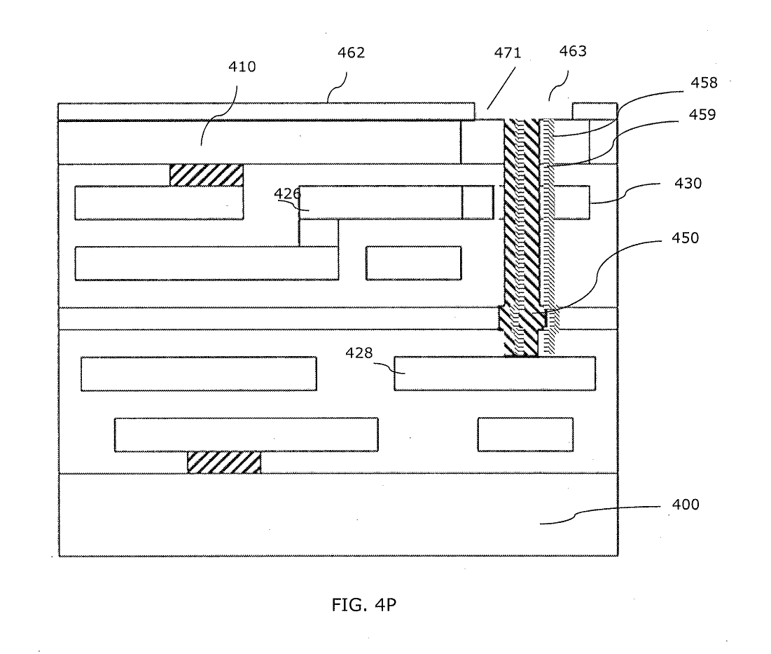

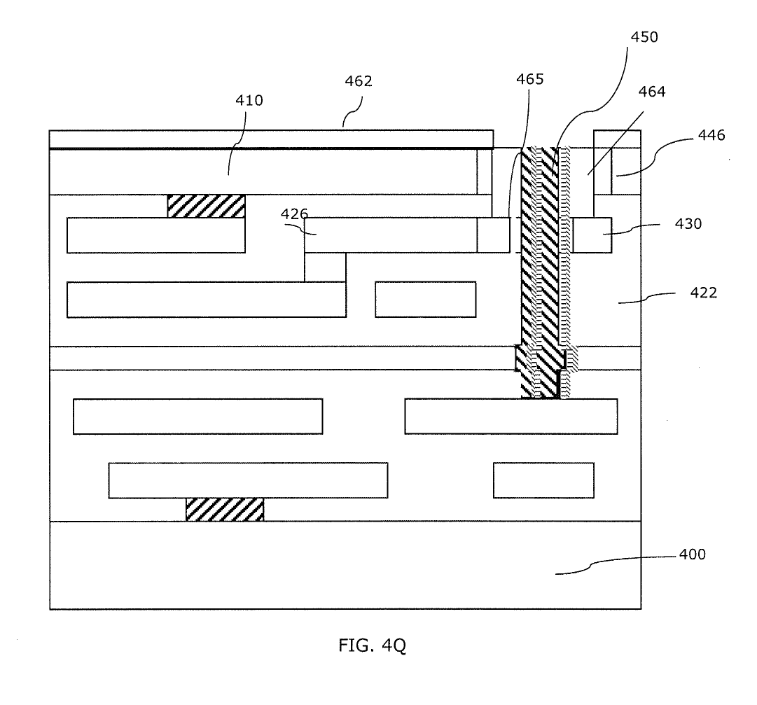

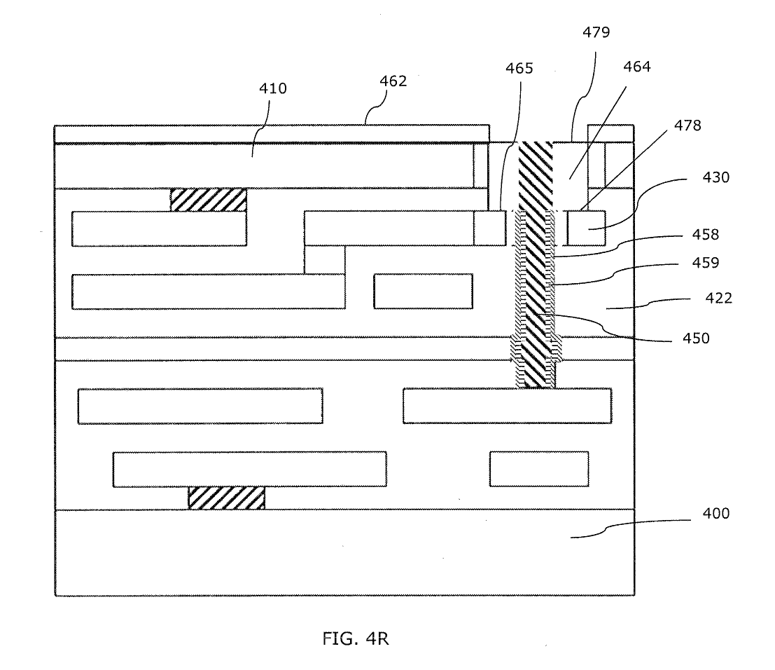

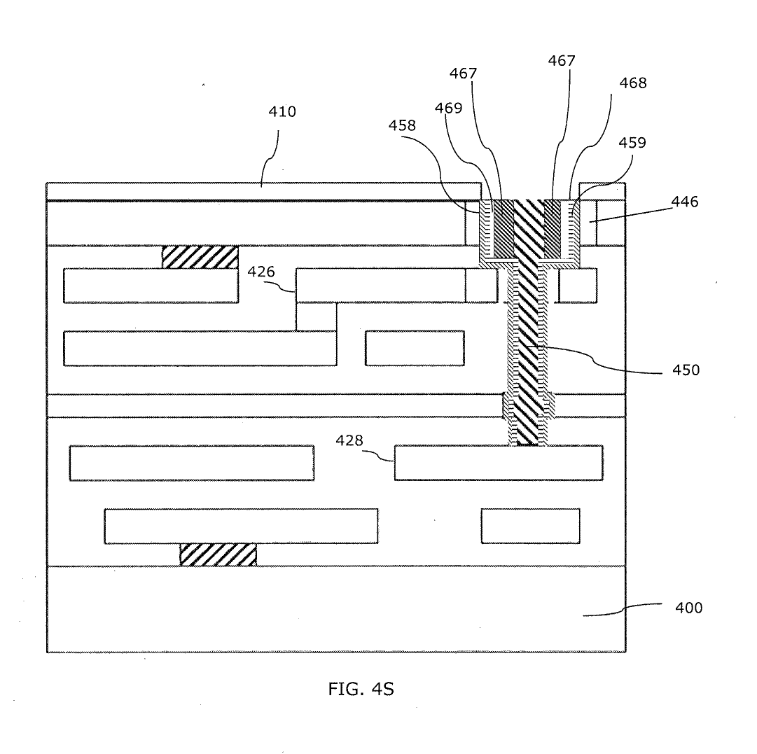

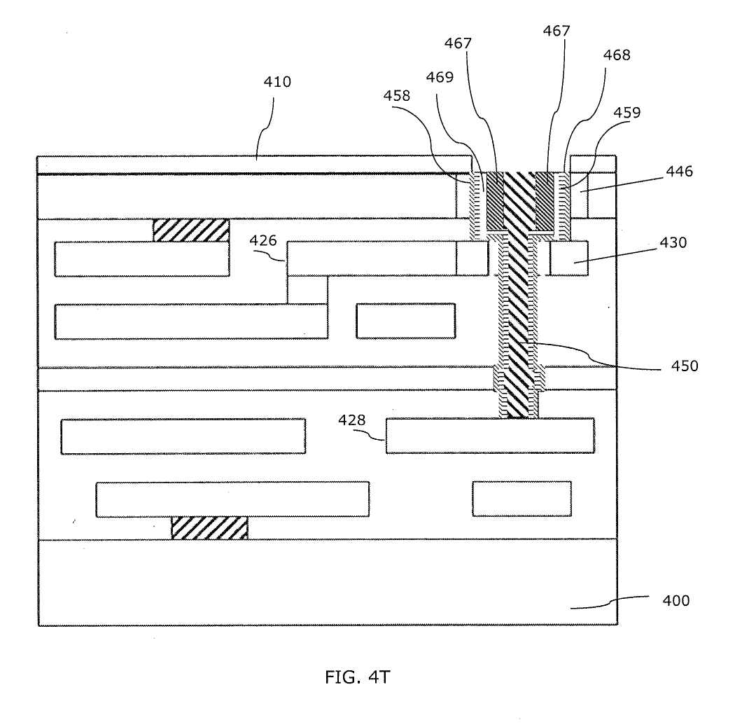

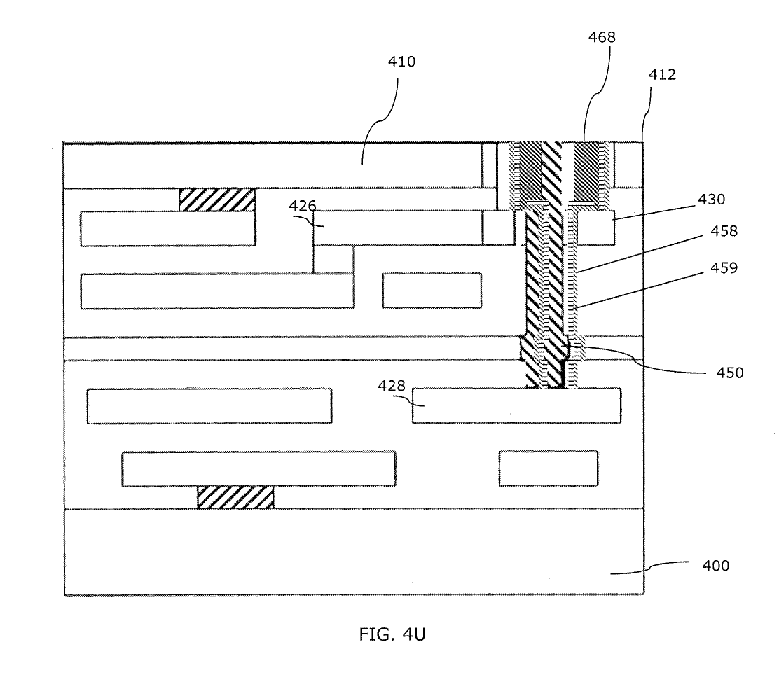

FIGS. 4A-4U illustrate a sequence for fabricating a deep pillar nail head via for connecting metal layers of chips bonded in a face-against-face configuration. FIGS. 4A-4U depict many elements that are also illustrated in FIGS. 3A-3C, and described above. In such cases, the elements depicted in FIGS. 4A-4U should be labeled as a 4 series (e.g., 420) to a corresponding three-series (e.g., 320) element depicted in FIGS. 3A-3C.

FIG. 4A illustrates a face-against-face configuration similar to that of FIG. 3C, wherein the substrate 410 has been thinned from the back surface 412. A metal shield layer 440 may be deposited on the back surface of thinned substrate 410. The metal shield layer may provide added etch resistance during the following etching of the silicon substrate 410. The metal shield layer may be formed of molybdenum, nickel, or any other suitable shield material. The chemistry of this layer preferably should be orthogonal to the etch chemistries for the other layers employed in the process, to avoid damaging these other layers when the shield layer is removed. A mask layer (not shown) may be formed on the metal shield layer 440. The mask layer, which may be photoresist, or any other suitable material, may be deposited, or formed by any suitable method. The mask layer is patterned to form an etch mask for etching the metal shield layer 440.

The fabrication of the deep pillar nail head via proceeds in FIG. 4B, with the etching of an opening 444 in the thinned substrate 410. It is desired to use an etch technology with a high anisotropy, which may be a wet etch or a dry etch, as the invention is not limited in this respect. For instance, SF₆ may be used as the etchant. As shown in FIG. 4B, the walls 443 of the opening 444 are approximately aligned with the outer edges 431 of the collet 430. While this need not be the case, good alignment of the walls 443 with the outer edges 431 of collet 430 may facilitate forming a good contact between the nail head (shown later) and the collet 430. It is desirable that the walls 443 of opening 444 not be aligned outside the outer edges 431, which might lead to the undesired formation of a tunnel outside the collet during etching.

As shown in FIG. 4C, the metal shield layer 440 (shown in FIG. 4B) is removed by any suitable method.

FIG. 4D illustrates the back-filling of opening 444 in the substrate 410. This is performed at least in part, as will be seen more clearly in FIG. 4F, to avoid forming a Schottky-barrier junction between the deep pillar via (shown later) and the substrate 410. The back-filling of opening 444 in the substrate 410 may include depositing or otherwise forming layer 446, which may be SiO₂ or any other suitable dielectric material, typically an oxide. The formation of layer 446 may be performed by chemical vapor deposition (CVD) or any other suitable deposition or selective growth process. After forming layer 446, chemical-mechanical polishing (CMP), or any other suitable planarization process, may be performed so that the upper surface of layer 446 is substantially coplanar with back surface 412 of substrate 410.

FIG. 4E shows the metal shield layer 448 after it has been patterned and the mask layer has been removed. For example, if the mask layer is formed of photoresist, it may be removed by ashing. The metal shield layer may be etched using any suitable etchant technology, including wet etch or dry etch technologies, as the invention is not limited in this respect. After patterning, the metal shield layer forms an etch mask for subsequent processing. The patterning includes opening 447, formed directly above collet 430. As illustrated, the walls 449 of opening 447 are disposed such that opening 447 is narrower than the width of collet 430, defined by the inner edges 429.

FIG. 4F illustrates an early stage of the formation of a tunnel 450. The tunnel 450 is formed by etching through the back-filled layer 446 and the dielectric layer 422. At this stage, the tunnel 450 extends to the bonding layer 420. Tunnel 450 may be formed by a directional etch, such as a deep reactive ion etch (DRIE), using any suitable etchant. For example, if dielectric layer 422 and back-filled layer 446 are SiO₂, any of the fluoro-methyl etch candidates may be used, such as CF₄, CF₃H, or CFH₃. These may be used with or without argon. An inductively coupled plasma (ICP) etch may also be used in addition to, or in place of, DRIE. In one embodiment, the formation of tunnel 450 is performed using the Bosch process of repeated deposition and etching steps, which may be used with DRIE or ICP.

The alignment of the tunnel 450 is such that dielectric portions 451 remain between the tunnel 450 and the collet 430. The dielectric portions 451 prevent the growth of metal between the inner edges 429 of the collet 430 when the tunnel 450 is later filled to form the deep pillar via.

As shown in FIG. 4G, the formation of tunnel 450 continues by etching bonding layer 420 using, for example, DRIE or ICP with any suitable etchant. If the bonding layer 420 is a polymeric glue layer, then oxygen may serve as the etchant, possibly enhanced by Bosch reoxidation. Depending on the composition of bonding layer 420, and the type of etch used, a lateral etch may necessarily accompany the vertical etch during this step. However, the lateral etch is not required, and the invention is not limited in this respect. It is desired to minimize the amount of lateral etching.

FIG. 4H illustrates the continued formation of tunnel 450. The dielectric layer 424 is etched using DRIE, or ICP, with an appropriate etchant. The etching may again proceed by the Bosch process. If dielectric layer 424 is SiO₂, then any of the fluoro-methyl etch candidates may be used, such as CF₄, CF₃H, or CFH₃. These may be used with or without argon. The etching proceeds to the metallization layer 428, which operates as a natural etch stop.

With the tunnel 450 completed, the metal shield layer 448 may be removed from the back surface 412 of substrate 410 by any suitable method. The process proceeds with the formation of the deep pillar nail head via. As shown in FIG. 4I, a barrier layer 458 is deposited on the walls and floor of tunnel 450. The barrier layer 458 may be W, Ti, Ta, TiN, TaN or any other suitable material, and is used to prevent diffusion of the later-deposited pillar material into the surrounding dielectric layers 422 and 424, and the bonding layer 420. The barrier layer 458 may be deposited by a highly conformal CVD process, or by atomic layer deposition, and thus may be very thin.

An adhesion promoter reactor is then applied to tunnel 450. The adhesion promoter reactor may be applied to barrier layer 458, or to any other material located on tunnel 450. The adhesion promoter reactor anchors an adhesion promoter 461 to barrier layer 458, or to any other material located on tunnel 450. As shown in FIG. 43, the adhesion promoter 461 is attached to the perimeter of tunnel 450. In preferred embodiments, the adhesion promoter reactor may be SiO₂, or any other material, and is applied to the barrier layer 458 using chemical vapor deposition (CVD) or another suitable deposition process. The adhesion promoter 461 may be A-174, or any other material used to promote adhesion according to aspects of the invention.

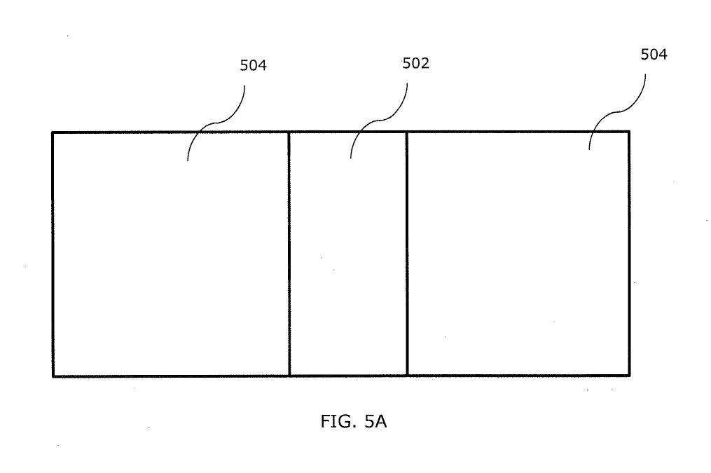

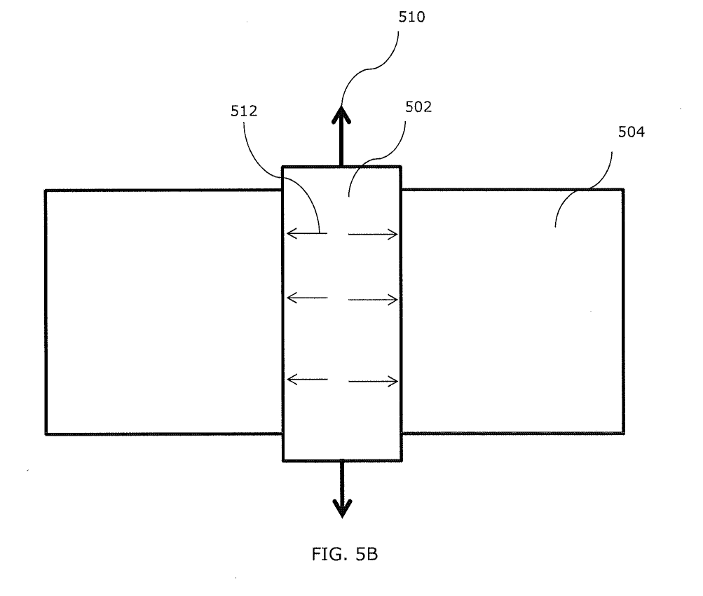

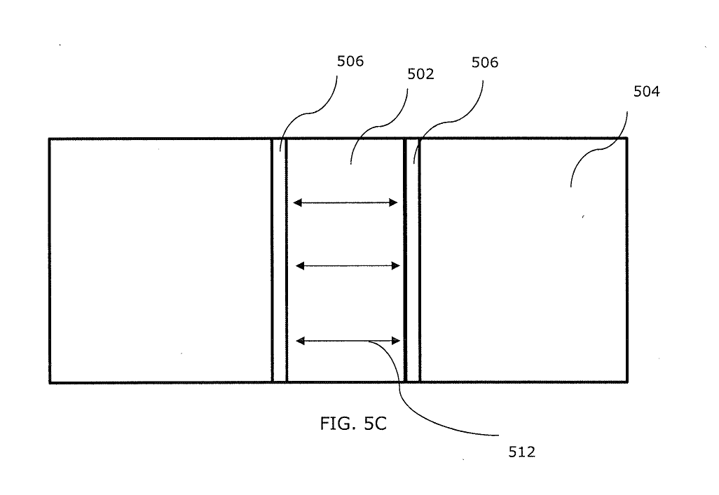

FIG. 4K illustrates a cushion layer 459 being applied to the tunnel 450. The cushion layer 459 may be applied to the entire perimeter of tunnel 450, or to only a portion of tunnel 450. Further, the cushion layer 459 may be deposited on the adhesion promoter 461, or to any other material on the tunnel 450, including the tunnel 450 perimeter itself. In a preferred embodiment, the cushion layer 459 is comprised of a vapor deposition polymer (VDP), or another material. In a more preferred embodiment, the cushion layer 459 may be comprised of Parylene. The cushion layer 459 is used to provide a cushion, buffer, and/or barrier between the tunnel 450 and the materials surrounding tunnel 450. For illustration purposes, the cushion layer 459 is described below in relation to simplified FIGS. 5A-5C.

FIG. 5A shows a figure of a conventional tunnel, such as a Through Silicon Via (TSV) 502, located within a die 504. In a preferred embodiment, the die 504 may be made of silicone (Si), or some other material. The TSV 502 may be a metal used by those skilled in the art for vias, such as copper (Cu) or Tungsten (W). Cu is typically a preferred metal due to its low resistance to electrical current and thermal conductivity. Therefore, Cu will be discussed below, for illustration purposes only.

As described above, the TSV 502 and the die 504 typically are formed of different materials, e.g., silicon for the die and copper for the TSV. As a result, unwanted problems may arise when a conventional TSV 502 and a conventional die 504 are heated. As one example, when heating the TSV 502 and the die 504 (e.g., during a soldering process), the Cu in the TSV 502 may enlarge to a greater degree than the enlargement of the die 504, formed of Si. This is due to the Cu, in the TSV 502, having a greater thermal expansion coefficient than the Si comprising the die 504. The enlargement of the Cu TSV 502 during heating, due to Cu's coefficient of thermal expansion, is illustrated as element 512 on FIG. 5B.

Further, the Cu in the TSV 502 has a lower Vickers hardness than the Si die 504 surrounding the TSV 502. In other words, the Cu forming the TSV 502 is softer than the surrounding Si forming the die 504. Because the expanding Cu (depicted as element 512) is softer than the surrounding Si die 504, the expanding Cu in the TSV 502 may be unable to move the Si die 504, at least, without damaging/cracking the die 504. As a result, during heating of the materials, the expanding Cu may be caused to extrude 510 from the ends of the TSV 502. This extrusion of Cu, depicted as element 510 in FIG. 5B, may result in failure of the chip.

The present invention eliminates, or mitigates, the extrusion 510 of Cu from the ends of the TSV 502. One embodiment of the present invention is shown in FIG. 5C. As shown in FIG. 5C, a cushion layer 506 is applied between TSV 502 and die 504. The cushion layer 506 accepts the forces exerted by the Cu TSV 502, and the Si die 504, as each material is respectively heated, for example. As one example, the cushion layer 506 may be formed of elastic and/or soft material to accept the Cu TSV 502 as it expands during heating. Further, the cushion layer 506 is intended to substantially retain its own shape/size when the temperature excursion ceases.

In preferred embodiments, the cushion layer 506 attaches to the TSV 502, preferably indirectly via an adhesion promoter (discussed above). In some embodiments, the cushion layer may be comprised of a vapor depositable polymer, e.g., Parylene. Further examples of a vapor depositable polymer may include Parylene-X, Parylene dimer, etc. Because Parylene is soft and elastic, applying Parylene as a cushion layer 506 allows the of Cu within the TSV 502 to expand with minimal resistance when temperatures rise, and relax back to its prior thickness when the temperature excursion ceases. Further, due to the softness and elasticity of Parylene, the cushion layer 506 will elastically return to at least substantially its normal thickness when the temperature excursion is over. By providing a soft and/or elastic cushion layer 506 between the TSV 502 and the die 504, the TSV 502 and die 504 can be exposed to increased temperatures without resulting in the TSV material extruding from the ends of the TSV tunnel. By eliminating, or mitigating, the Cu extruding from TSV 502, less damage to the TSV 502 and/or die 504 will result.

Returning to FIG. 4K, the cushion layer 459, e.g., Parylene, etc., is applied to the tunnel 450, preferably to barrier layer 458 deposited on tunnel 450. The cushion layer 459, however, is not limited in this respect. Cushion layer 459 may be applied to any material formed in tunnel 450, including the tunnel 450 itself. As indicated above, in preferred embodiments, the cushion layer 459 may be comprised of Parylene, or another soft and/or elastic material providing a cushion and/or barrier between the tunnel 450 and its surrounding material.

As illustrated in FIG. 4L, the cushion layer 459 and/or the barrier layer 458 should be removed from the floor of the tunnel 450. In one embodiment, a bias directional etch may be used to remove the barrier layer 458 and/or the cushion layer 459 (e.g., Parylene) from the floor of tunnel 450.

The process proceeds in FIGS. 4M-4O with the plating of copper 460 from the bottom of tunnel 450, upward. It is preferable to fill the tunnel with copper vertically, since lateral growth of copper within the tunnel may lead to the formation of voids, and thus increased via resistance and decreased performance. The copper may be plated by liquid processes or CVD, as the invention is not limited in this respect.

As shown in FIG. 4N, the plating of copper 460 proceeds to approximately the top of bonding layer 420.

As shown in FIG. 4O, the copper 460 is plated to approximately the top of tunnel 450. The tunnel 450 is filled with copper 460 extending to a height approximately planar with the back surface 412 of substrate 410.

FIG. 4P shows the metal shield layer 462 after it has been patterned and the mask layer has been removed. For example, if the mask layer is formed of photoresist, it may be removed by ashing. The metal shield layer may be etched using any suitable etchant, including wet etch or dry etch, as the invention is not limited in this respect. After patterning, the metal shield layer forms an etch mask for subsequent processing. The patterning includes openings such as 463. In the illustrated embodiment, the walls 471 of opening 463 are aligned over the collet 430.

As illustrated in FIG. 4Q, a trench 464 is etched through layer 446 (see FIG. 4E), fully or partially removing layer 446 and a portion of dielectric layer 422 such that the bottom of the trench 464 coincides with the upper surface 465 of the collet 430. A cleaning step may be performed to remove any detritus which may form on the upper surface 465 of the collet 430 during the etching of trench 464.

Cushion layer 459, barrier layer 458, and/or the like, are removed from the top sides of tunnel 450, as shown in FIG. 4R. In particular, cushion layer 459 and/or barrier layer 458 are removed from each top side of tunnel 450, beginning with the bottom surface 478 of trench 464 and ending at the top surface 479 of trench 464. The adhesion promoter reactor and the adhesion promoter may also be removed from the top sides of tunnel 450. Cushion layer 459 and/or barrier layer 458, for example, are removed from the top sides of the tunnel 450 so that conduction may occur between the top sides of the tunnel 450 and the nail head formed in trench 464.

As illustrated in FIG. 4S, barrier layer 458 may be deposited on trench 464 to prevent diffusion of copper into the surrounding layers. The barrier layer deposited on trench 464 may be of the same material as the barrier layer described above and deposited on the sides and floor of tunnel 450. Further, according to aspects of this invention, the cushion layer 459 may be deposited in trench 464 to provide a soft and/or elastic cushion between the trench 464 and materials surrounding the trench 464, including substrate 410. As discussed above, the cushion layer 459 may be Parylene, or other materials described throughout the specification for providing a soft and/or elastic cushion between tunnel 450 and surrounding materials. Metal shield layer 462 may also be removed at this time by any suitable method. The copper is subsequently plated or deposited to form an inner portion 467 of the nail head 468, an early stage of which is shown on FIG. 4S.

FIG. 4T shows the cushion layer 459, barrier layer 458, etc. being removed from the floor of outer portion 469 of the nail head 468. The adhesion promoter and adhesion promoter reactor (not shown) may also be removed from the floor of the outer portion 469. The cushion layer 459, barrier layer 458, etc., may be removed from the floor of the nail head using many methods known by those skilled in the art, e.g., directional etching. Directional etchings according to aspects of the invention may include, but are not limited to, biased oxygen plasma and/or argon etching. Cushion layer 459, barrier layer 458, etc. are removed from the floor of the outer portion 469 of the nail head 468 so that a full circuit may exist from the metal (e.g., copper), located in the outer portion 469 of the nail head 468, to the collet 430 located just below the outer portion 469 of the nail head 468.

As shown in FIG. 4U, nail head 468 may then be filled with a metal, e.g., copper. The filling of the metal, for example, copper, for the nail head 468 may proceed in a non-uniform manner, leaving excess copper. The excess copper may be removed by any suitable processing, for example, chemical-mechanical polishing (CMP). The top surface of nail head 468 should be approximately level with back surface 412 of substrate 410, and accessible for forming external contacts.

It should be appreciated that the illustrative processing sequences described thus far are non-limiting, and that additional or alternative processing sequences may readily occur to those of skill in the art. Depending on the exact order of steps, or the exact etchants used, certain steps may not be necessary. For example, depending on the etchants, metal shield layers and/or mask layers may not be needed. In addition, although the substrates have been described as being silicon, it is possible to use substrates of other materials. If the substrates are of a material other than silicon (such as SiC or GaAs), then the etch fluids and conditions, dielectric layers, glue layer, etc. would all need to be changed appropriately. Such changes or modifications to the above described materials and processes do not depart from the spirit of the invention and such adaptations are well within the abilities of those skilled in the art of semiconductor fabrication.

It should also be appreciated that the deep pillar nail head via may be formed in the absence of a collet, or with a collet that is part of the deep pillar nail head via. In other words, the deep pillar nail head via and the collet need not be distinct structures, and the invention is not limited in this respect.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed:

1. An integrated circuit assembly comprising:
a first chip having a face surface comprising at least one first device, and a back surface;
a second chip having a face surface comprising at least one second device, the first chip and the second chip being bonded in a face-against-face contact configuration;
a via comprising a pillar portion disposed to pass through the first chip and the second chip, wherein the via is surrounded by at least one material of the respective first chip and the second chip; and
a cushion layer encapsulating at least a portion of the via, the cushion layer being formed between the via and the at least one material surrounding the via.

2. The integrated circuit assembly of claim 1, wherein the cushion layer is soft or elastic.

3. The integrated circuit assembly of claim 1, wherein a material forming the cushion layer is a vapor depositable polymer.

4. The integrated circuit assembly of claim 3, wherein the vapor depositable polymer is Parylene.

5. The integrated circuit assembly of claim 1, wherein:
the via, comprising a pillar portion, includes a floor; and
the cushion layer is absent from the floor of the via.

6. The integrated circuit assembly of claim 1, wherein an adhesion promoter, to promote adhesion of the cushion layer to the via, is disposed on at least a portion of the via.

7. The integrated circuit assembly of claim 6, wherein the adhesion promoter is A-174.

8. The integrated circuit assembly of claim 1, wherein the via is formed of a metal.

9. The integrated circuit assembly of claim 8, wherein the metal comprises copper.

10. The integrated circuit assembly of claim 9, further comprising a barrier layer encapsulating at least a portion of the via and disposed to prevent diffusion of the copper into materials surrounding the via.

11. The integrated circuit assembly of claim 10, wherein the cushion layer is formed between the barrier layer and the metal comprising the via.

12. The integrated circuit assembly of claim 1, further comprising:
a bonding layer used to bond the face of the first chip and the face of the second chip to each other in the face-against-face contact configuration; and
the via passes through the bonding layer.

13. A multi-wafer circuit assembly comprising:
a first wafer having a face surface comprising at least one first device and a back surface;
a second wafer having a face surface comprising at least one second device, the first wafer and the second wafer being bonded in a face-against-face contact configuration; and
a via comprising a pillar portion disposed to pass through the first wafer and the second wafer, wherein the via is surrounded by at least one material of the respective first wafer and the second wafer; and
a cushion layer encapsulating at least a portion of the via and formed between the via and the at least one material surrounding the via.

14. The multi-wafer circuit assembly of claim 13, wherein the cushion layer is soft or elastic.

15. The multi-wafer circuit assembly of claim 13, wherein the material forming the cushion layer is a vapor depositable polymer.

16. The multi-wafer circuit assembly of claim 15, wherein the vapor depositable polymer is Parylene.

17. The multi-wafer circuit assembly of claim 13, wherein:
the via, comprising a pillar portion, includes a floor; and
the cushion layer is absent from the floor of the via.

18. The multi-wafer circuit assembly of claim 13, wherein the via is formed of a metal.

19. A method of interconnecting a first chip and a second chip, the method comprising:
bonding the first chip and the second chip in a face-against-face configuration;
forming a via at least partially within the first chip and the second chip, wherein the via is surrounded by at least one material of the respective first chip and the second chip; and
depositing a cushion layer on a portion of the via, wherein the cushion layer is formed between the via and the at least one material surrounding the via.

20. The method of claim 19, wherein the cushion layer is soft or elastic.

21. The method of claim 19, wherein the material forming the cushion layer is a vapor depositable polymer.

22. The method of claim 21, wherein the vapor depositable polymer is Parylene.

23. The method of claim 19, wherein the method further comprises removing the cushion layer, formed between the via and the at least one material surrounding the via, from a floor of the pillar.

24. The method of claim 19, wherein an adhesion promoter, to promote the adhesion of the cushion layer to the via, is disposed on at least a portion of the via.

25. The method of claim 24, wherein the adhesion promoter is A-174.

26. The method of claim 19, wherein the via is formed of a metal.

27. The method of claim 19, wherein the via passes through a bonding layer used to bond a face of the first chip and a face of the second chip to each other.

28. The method of claim 19, further comprising:
prior to depositing the cushion layer on the via, encapsulating the via with a barrier layer disposed to prevent diffusion of the copper into materials surrounding the via.
